(19) United States
(12) Patent Application Publication
(10) Pub. No.: US 2015/0036440 A1
(43) Pub. Date: Feb. 5, 2015

(54) SEMICONDUCTOR DEVICES AND SEMICONDUCTOR SYSTEMS INCLUDING THE SAME

(71) Applicant: SK hynix Inc., Icheon-si (KR)

(72) Inventors: Jin Ah KIM, Icheon-si (KR); Sang Il PARK, Suwon-si (KR)

(73) Assignee: SK hynix Inc., Icheon-si (KR)

(21) Appl. No.: 14/133,925

(22) Filed: Dec. 19, 2013

(30) Foreign Application Priority Data
Jul. 30, 2013 (KR) 10-2013-0089982

(51) Int. Cl. G11C 11/406

(52) U.S. Cl. CPC G11C 11/40618
USPC 365/189.05; 365/222; 365/230.03

(57) ABSTRACT

Semiconductor devices are provided. The semiconductor device includes a counter configured to output a first internal address signal counted in synchronization with a refresh clock signal during a refresh operation, an address transmitter configured to output a first external signal as a second internal address signal in response to a refresh pulse, and a bank address generator configured to decode the first internal address signal or the second internal address signal in response to a selection signal to generate a bank address signal for accessing a bank.

### CROSS-REFERENCE TO RELATED APPLICATION

The present application claims priority under 35 U.S.C 119(a) to Korean Application No. 10-2013-0089982, filed on Jul. 30, 2013, in the Korean Intellectual Property Office, which is incorporated herein by reference in its entirety as set forth in full.

### BACKGROUND

1. Technical Field

Embodiments of the present disclosure relate to semiconductor integrated circuits and, more particularly, to semiconductor devices and semiconductor systems including the same.

2. Description of Related Art

Semiconductor devices may be typically categorized as either volatile memory devices or nonvolatile memory devices. The volatile memory devices lose their stored data when their power supplies are interrupted. In contrast, the nonvolatile memory devices retain their stored data even when their power supplies are interrupted. The volatile memory devices may include dynamic random access memory (DRAM) devices and static random access memory (SRAM) devices.

Each of the DRAM devices may include a cell array portion composed of a plurality of cells, and each of cells may typically store one bit of digital information (i.e., a single data) therein. Each of the DRAM cells may include a single cell transistor and a single cell capacitor. The data may be stored in the cell capacitors through the cell transistors. However, the data stored in the cell capacitors of the DRAM cells may be lost due to cell leakage currents as the time elapses even while a power supply is applied to the DRM cells. Thus, in order to retain the data stored in the DRAM cells, the DRAM devices are basically accompanied with operations for periodically rewriting the data from external systems, which are often called “refresh” operations.

As the DRAM devices become more highly integrated, the cell array portion in each DRAM device may be divided into a plurality of banks. Recently, each of the DRAM devices has been designed to include eight or more banks. In such a case, an address decoding operation for generating bank address signals may be required to execute the refresh operation of the DRAM device including a plurality of banks.

### SUMMARY

Various embodiments are directed to semiconductor devices and semiconductor systems including the same.

According to various embodiments, a semiconductor device includes a counter configured to output a first internal address signal that is counted in synchronization with a refresh clock signal generated during a refresh operation, an address transmitter configured to output a first external signal as a second internal address signal in response to a refresh pulse generated during the refresh operation, and a bank address generator configured to decode the first internal address signal or the second internal address signal in response to a selection signal to generate a bank address signal for accessing a bank. The selection signal is generated in response to a second external signal.

According to further embodiments, a semiconductor system includes a controller and a semiconductor device. The controller generates an external command signal, a first external signal and a second external signal. The semiconductor device receives the external command signal to output a first internal address signal that is counted in synchronization with a refresh clock signal during a refresh operation, generates a second internal address signal from the first external signal during the refresh operation, and decodes the first internal address signal or the second internal address signal in response to a selection signal to generate a bank address signal for accessing a bank during the refresh operation. The selection signal is generated from the second external signal.

According to further embodiments, a semiconductor system includes a controller configured to generate an external command signal, a first external signal and a second external signal, a command decoder configured to decode the external command signal to generate a refresh signal corresponding to an internal command signal for executing a refresh operation, a clock generator configured to generate a refresh clock signal when the refresh signal is enabled, a pulse generator configured to generate a refresh pulse when the refresh signal is enabled, a counter configured to output a first internal address signal that is counted in synchronization with the refresh clock signal, an address transmitter configured to output the first external signal as a second internal address signal in response to the refresh pulse, and a bank address generator configured to decode the first internal address signal or the second internal address signal in response to a selection signal to generate a bank address signal for accessing a bank to which the refresh operation is applied.

### BRIEF DESCRIPTION OF THE DRAWINGS

Embodiments of the present invention will become more apparent in view of the attached drawings and accompanying detailed description, in which:

FIG. 1 is a block diagram illustrating a semiconductor system according to an embodiment of the present invention;

FIG. 2 is a logic circuit diagram illustrating an address transmitter included in the semiconductor system of FIG. 1;

FIG. 3 is a logic circuit diagram illustrating a selection signal generator included in the semiconductor system of FIG. 1;

FIG. 4 is a logic table illustrating an operation of the selection signal generator shown in FIG. 3; and

FIG. 5 is a logic circuit diagram illustrating a bank address generator included in the semiconductor system of FIG. 1.

### DETAILED DESCRIPTION OF THE EMBODIMENTS

Various embodiments of the present invention will be described hereinafter with reference to the accompanying drawings. However, the embodiments described herein are for illustrative purposes only and are not intended to limit the scope of the present invention.

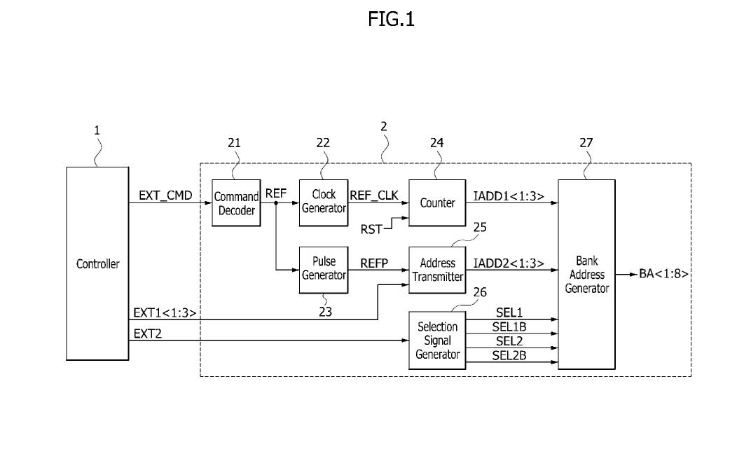

Referring to FIG. 1, a semiconductor system according to an embodiment of the present invention may include a controller 1 and a semiconductor device 2. The controller 1 may generate an external command signal EXT_CMD, a first external signal EXT1<1:3> and a second external signal EXT2 and may apply the external command signal EXT_CMD, the first external signal EXT1<1:3> and the second external signal EXT2 to the semiconductor device 2. The external command signal EXT_CMD, the first external signal EXT1<1:3> and the second external signal EXT2 may be inputted to the semiconductor device 2 through separate pins or common pins. For example, in the event that the semiconductor device 2 is designed to receive a command signal and an address signal through the common pins, the external command signal EXT_CMD, the first external signal EXT1<1:3> and the second external signal EXT2 may be inputted to the semiconductor device 2 through the common pins. The semiconductor device 2 may include a command decoder 21, a clock generator 22, a pulse generator 23, a counter 24, an address transmitter 25, a selection signal generator 26 and a bank address generator 27.

The command decoder 21 may decode the external command signal EXT_CMD to generate a refresh signal REF corresponding to an internal command signal which is enabled to execute a refresh operation. The clock generator 22 may generate a refresh clock signal REF_CLK when the refresh signal REF is enabled. The pulse generator 23 may generate a refresh pulse REFP when the refresh signal REF is enabled. The counter 24 may output a first internal address signal IADD1<1:3> that is sequentially counted in synchronization with the refresh clock signal REF_CLK during a refresh operation. The counter 24 may initialize the first internal address signal IADD1<1:3> to a predetermined level combination when a reset signal RST is enabled. The address transmitter 25 may output the first external signal EXT1<1:3> as a second internal address signal IADD2<1:3> when the refresh pulse REFP is inputted thereto during the refresh operation. In various embodiments, a level combination of the second internal address signal IADD2<1:3> may be set to be identical to a level combination of the first external signal EXT1<1:3>. Alternatively, a level combination of the second internal address signal IADD2<1:3> may be set to be different from a level combination of the first external signal EXT1<1:3>. The selection signal generator 26 may set levels of a first selection signal SEL1, a first complementary selection signal SEL1B, a second selection signal SEL2 and a second complementary selection signal SEL2B according to a level of the second external signal EXT2. The bank address generator 27 may decode the first internal address signal IADD1<1:3> or the second internal address signal IADD2<1:3> in response to the first and second selection signals SEL1 and SEL2 and the first and second complementary selection signals SEL1B and SEL2B to generate first to eighth bank address signals BA<1:8>, one of which is selectively enabled to access one of first to eighth banks (not shown) to which the refresh operation may be applied. Further, the first selection signal SEL1 and the second selection signal SEL2 may be generated in response to the second external signal EXT2.

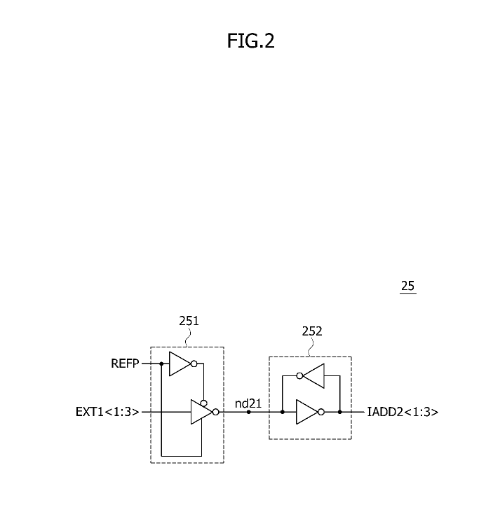

Referring to FIG. 2, the address transmitter 25 may include a transmitter 251 and a latch unit 252. The transmitter 251 may inversely buffer the first external signal EXT1<1:3> in synchronization with the refresh pulse REFP during a period that the refresh pulse REFP having a logic “high” level is created by the enabled refresh signal REF, thereby outputting the inversely buffered first external signal through a node ND21. The latch unit 252 may inversely buffer a signal on the node ND21 to output the inversely buffered signal as the second internal address signal IADD2<1:3> and may latch the signal on the node ND21 and the second internal address signal IADD2<1:3>. That is, the address transmitter 25 may buffer the first external signal EXT1<1:3> to output the buffered first external signal EXT1<1:3> as the second internal address signal IADD2<1:3> while the refresh pulse REFP having a logic “high” level is created by the enabled refresh signal REF.

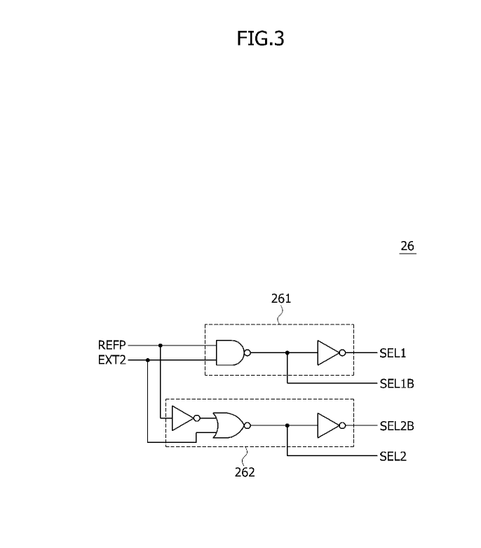

Referring to FIG. 3, the selection signal generator 26 may include a first logic unit 261 and a second logic unit 262. During a period that the refresh pulse REFP having a logic “high” level is created by the enabled refresh signal REF, the first logic unit 261 may inversely buffer the second external signal EXT2 to generate the first complementary selection signal SEL1B and may inversely buffer the first complementary selection signal SEL1B to generate the first selection signal SEL1. During the period that the refresh pulse REFP having a logic “high” level is created by the enabled refresh signal REF, the second logic unit 262 may inversely buffer the second external signal EXT2 to generate the second selection signal SEL2 and may inversely buffer the second selection signal SEL2 to generate the second complementary selection signal SEL2B.

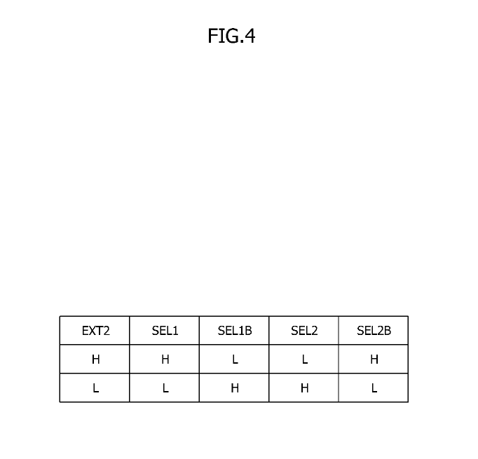

Referring to FIG. 4, the levels of the first and second selection signals SEL1 and SEL2 and the first and second complementary selection signals SEL1B and SEL2B may be determined according to the level of the second external signal EXT2. That is, when the second external signal EXT2 has a logic “high” level, the first selection signal SEL1, the first complementary selection signal SEL1B, the second selection signal SEL2 and the second complementary selection signal SEL2B may be generated to have a logic “high” level, a logic “low” level, a logic “low” level and a logic “high” level, respectively. In addition, when the second external signal EXT2 has a logic “low” level, the first selection signal SEL1, the first complementary selection signal SEL1B, the second selection signal SEL2 and the second complementary selection signal SEL2B may be generated to have a logic “low” level, a logic “high” level, a logic “high” level and a logic “low” level, respectively.

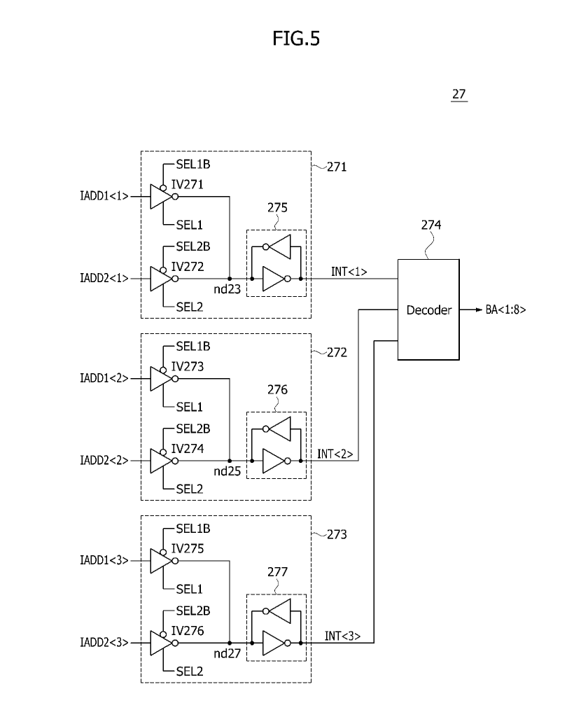

Referring to FIG. 5, the bank address generator 27 may include a first internal signal generator 271, a second internal signal generator 272, a third internal signal generator 273 and a decoder 274.

The first internal signal generator 271 may be configured to include a couple of inverters IV271 and IV272 and a first latch unit 275. The inverter IV271 may be turned on to output an inversed signal of a first bit IADD1<1> of the first internal address signal IADD1<1:3> through a node ND23 when the first selection signal SEL1 has a logic “high” level and the first complementary selection signal SEL1B has a logic “low” level. The inverter IV272 may be turned on to output an inversed signal of a first bit IADD2<1> of the second internal address signal IADD2<1:3> through the node ND23 when the second selection signal SEL2 has a logic “high” level and the second complementary selection signal SEL2B has a logic “low” level. The first latch unit 275 may inversely buffer a signal on the node ND23 to generate a first internal signal INT<1> and may latch the signal on the node ND23 and the first internal signal INT<1>. The first internal signal generator 271 may be configured to receive the first and second selection signals SEL1 and SEL2 to selectively output the first internal address signal IADD1<1:3> or the second internal address signal IADD2<1:3> as the first internal signal INT<1>.

The second internal signal generator 272 may be configured to include a couple of inverters IV273 and IV274 and a second latch unit 276. The inverter IV273 may be turned on to output an inversed signal of a second bit IADD1<2> of the first internal address signal IADD1<1:3> through a node ND25 when the first selection signal SEL1 has a logic “high” level and the first complementary selection signal SEL1B has a logic “low” level. The inverter IV274 may be turned on to output an inversed signal of a second bit IADD2<2> of the second internal address signal IADD2<1:3> through the node ND25 when the second selection signal SEL2 has a logic “high” level and the second complementary selection signal SEL2B has a logic “low” level. The second latch unit 276 may inversely buffer a signal on the node ND25 to generate a second internal signal INT<2> and may latch the signal on the node ND25 and the second internal signal INT<2>. The second internal signal generator 272 may be configured to receive the first and second selection signals SEL1 and SEL2 to selectively output the first internal address signal IADD1<1:3> or the second internal address signal IADD2<1:3> as the second internal signal INT<2>.

The third internal signal generator 273 may be configured to include a couple of inverters IV275 and IV276 and a third latch unit 277. The inverter IV275 may be turned on to output an inversed signal of a third bit IADD1<3> of the first internal address signal IADD1<1:3> through a node ND27 when the first selection signal SEL1 has a logic “high” level and the first complementary selection signal SEL1B has a logic “low” level. The inverter IV276 may be turned on to output an inversed signal of a third bit IADD2<3> of the second internal address signal IADD2<1:3> through the node ND27 when the second selection signal SEL2 has a logic “high” level and the second complementary selection signal SEL2B has a logic “low” level. The third latch unit 277 may inversely buffer a signal on the node ND27 to generate a third internal signal INT<3> and may latch the signal on the node ND27 and the third internal signal INT<3>. The third internal signal generator 273 may be configured to receive the first and second selection signals SEL1 and SEL2 to selectively output the first internal address signal IADD1<1:3> or the second internal address signal IADD2<1:3> as the third internal signal INT<3>.

The decoder 274 may decode the first internal signal INT<1>, the second internal signal INT<2> and the third internal signal INT<3> to generate the first to eighth bank address signals BA<1:8>, one of which is selectively enabled to access one of a plurality of banks during a refresh operation. For example, when all the first, second and third internal signals INT<1>, INT<2> and INT<3> have a logic “low” level, the first bank address signal BA<1> may be selectively enabled to have a logic “high” level such that a refresh operation of a first bank is performed. A decoding scheme of the decoder 274 may change according to the embodiments. For example, in various embodiments, when all the first, second and third internal signals INT<1>, INT<2> and INT<3> have a logic “low” level, the eighth bank address signal BA<8> may be selectively enabled to have a logic “high” level such that a refresh operation of an eighth bank is performed.

As described above, the semiconductor system according to the embodiments may generate the first to eighth bank address signals BA<1:8> using the first internal address signal IADD1<1:3> internally counted as well as the second internal address signal IADD2<1:3> generated from the first external signal EXT1<1:3> outputted from the controller 1. As such, the semiconductor system may support diverse options with the operation for generating the first to eighth bank address signals BA<1:8> for the refresh operation, thereby providing users with conveniences.

What is claimed is:

1. A semiconductor device comprising:
a counter configured to output a first internal address signal counted in synchronization with a refresh clock signal during a refresh operation;
an address transmitter configured to output a first external signal as a second internal address signal in response to a refresh pulse; and
a bank address generator configured to decode the first internal address signal or the second internal address signal in response to a selection signal to generate a bank address signal for accessing a bank,
wherein the selection signal is generated in response to a second external signal.

2. The semiconductor device of claim 1, wherein the address transmitter includes:
a transmitter configured to buffer the first external signal in synchronization with the refresh pulse to output the buffered first external signal through an internal node; and
a latch unit configured to buffer a signal on the internal node to output the buffered signal as the second internal address signal and configured to latch the signal on the internal node and the second internal address signal.

3. The semiconductor device of claim 1,
wherein the selection signal includes a first selection signal and a second selection signal; and
wherein the first selection signal is enabled when the second external signal has a first logic level and the second selection signal is enabled when a second external signal has a second logic level.

4. The semiconductor device of claim 3, wherein when the first selection signal is enabled, the bank address generator decodes the first internal address signal to generate the bank address signal.

5. The semiconductor device of claim 4, wherein when the second selection signal is enabled, the bank address generator decodes the second internal address signal to generate the bank address signal.

6. The semiconductor device of claim 5, wherein the bank address generator includes:
a first internal signal generator configured to receive the first and second selection signals to selectively output the first internal address signal or the second internal address signal as a first internal signal;
a second internal signal generator configured to receive the first and second selection signals to selectively output the first internal address signal or the second internal address signal as a second internal signal;
a third internal signal generator configured to receive the first and second selection signals to selectively output the first internal address signal or the second internal address signal as a third internal signal; and
a decoder configured to decode the first, second and third internal signals to generate the bank address signal.

7. The semiconductor device of claim 1, further comprising a command decoder configured to decode an external command signal to generate a refresh signal corresponding to an internal command signal for executing the refresh operation.

8. The semiconductor device of claim 7, further comprising a clock generator configured to generate the refresh clock signal when the refresh signal is enabled.

9. The semiconductor device of claim 7, further comprising a pulse generator configured to generate a refresh pulse when the refresh signal is enabled.

10. A semiconductor system comprising:
a controller configured to generate an external command signal, a first external signal and a second external signal; and
a semiconductor device configured to receive the external command signal to output a first internal address signal that is counted in synchronization with a refresh clock signal during a refresh operation, configured to generate a second internal address signal from the first external signal during the refresh operation, and configured to decode the first internal address signal or the second internal address signal in response to a selection signal to generate a bank address signal for accessing a bank during the refresh operation,
wherein the selection signal is generated from the second external signal.

11. The semiconductor system of claim 10, wherein the semiconductor device includes:
a counter configured to output the first internal address signal that is counted in synchronization with the refresh clock signal;
an address transmitter configured to output the first external signal as the second internal address signal in response to a refresh pulse generated during a refresh operation; and
a bank address generator configured to decode the first internal address signal or the second internal address signal in response to the selection signal to generate the bank address signal.

12. The semiconductor system of claim 11, wherein the address transmitter includes:
a transmitter configured to buffer the first external signal in synchronization with the refresh pulse with a logic level created by to output the buffered first external signal through an internal node; and
a latch unit configured to buffer a signal on the internal node to output the buffered signal as the second internal address signal and configured to latch the signal on the internal node and the second internal address signal.

13. The semiconductor system of claim 11,
wherein the selection signal includes a first selection signal and a second selection signal; and
wherein the first selection signal is enabled when the second external signal has a first logic level and the second selection signal is enabled when the second external signal has a second logic level.

14. The semiconductor system of claim 13, wherein when the first selection signal is enabled, the bank address generator decodes the first internal address signal to generate the bank address signal.

15. The semiconductor system of claim 14, wherein when the second selection signal is enabled, the bank address generator decodes the second internal address signal to generate the bank address signal.

16. The semiconductor system of claim 15, wherein the bank address generator includes:
a first internal signal generator configured to receive the first and second selection signals to selectively output the first internal address signal or the second internal address signal as a first internal signal;
a second internal signal generator configured to receive the first and second selection signals to selectively output the first internal address signal or the second internal address signal as a second internal signal;
a third internal signal generator configured to receive the first and second selection signals to selectively output the first internal address signal or the second internal address signal as a third internal signal; and
a decoder configured to decode the first, second and third internal signals to generate the bank address signal.

17. The semiconductor system of claim 11, wherein the semiconductor device further includes a command decoder configured to decode the external command signal to generate a refresh signal corresponding to an internal command signal for executing the refresh operation.

18. The semiconductor system of claim 17, wherein the semiconductor device further includes a clock generator configured to generate the refresh clock signal when the refresh signal is enabled.

19. The semiconductor system of claim 17, wherein the semiconductor device further includes a pulse generator configured to generate a refresh pulse when the refresh signal is enabled.

20. A semiconductor system comprising:
a controller configured to generate an external command signal, a first external signal and a second external signal;
a command decoder configured to decode the external command signal to generate a refresh signal corresponding to an internal command signal for executing a refresh operation;
a clock generator configured to generate a refresh clock signal when the refresh signal is enabled;
a pulse generator configured to generate a refresh pulse when the refresh signal is enabled;
a counter configured to output a first internal address signal that is counted in synchronization with the refresh clock signal;
an address transmitter configured to output the first external signal as a second internal address signal in response to the refresh pulse; and
a bank address generator configured to decode the first internal address signal or the second internal address signal in response to a selection signal to generate a bank address signal for accessing a bank to which the refresh operation is applied.
